(19) United States
(12) Patent Application Publication
(10) Pub. No.: US 2013/0011984 A1
(43) Pub. Date: Jan. 10, 2013

(54) Using Hexachlorodisilane as a Silicon Precursor for Source/Drain Epitaxy

(75) Inventors: Kang-Wei Wang, Taipei City (TW); Clement Hsingjen Wann, Carmel, NY (US); Chih-Hsin Ko, Fongshan City (TW)

(73) Assignee: Taiwan Semiconductor Manufacturing Company, Ltd., Hsin-Chu (TW)

(21) Appl. No.: 13/178,330

(22) Filed: Jul. 7, 2011

(51) Int. Cl. H01L 21/336

(52) U.S. Cl. 438/285; 438/300; 257/E21.409

(57) ABSTRACT

A method includes forming a gate stack over a semiconductor region, and recessing the semiconductor region to form a recess adjacent the gate stack. A silicon-containing semiconductor region is epitaxially grown in the recess to form a source/drain region, wherein the step of epitaxially growing is performed using hexachlorodisilane as a precursor.

### BACKGROUND

In the formation of complementary metal-oxide-semiconductor (CMOS) devices, epitaxy processes are often used to form stressors in source and drain regions. For example, forming silicon germanium stressors may induce a compressive stress in the channel regions of p-type metal-oxide-semiconductor (PMOS) devices, and hence increase the hole mobility in the channel regions of the PMOS devices. Forming silicon carbon stressors may induce a tensile stress in the channel regions of n-type metal-oxide-semiconductor (NMOS) devices, and hence increase the electron mobility in the channel regions of the NMOS devices.

To form the silicon-containing stressors, silicon-containing precursors are used in the epitaxy processes for forming source/drain stressors. In the past, the silicon-containing precursors include silane, disilane, dichlorosilance (DCS), and trisilane (known as Silcore). These precursors, however, suffer from drawbacks and hence fail to fully meet the requirement of the source/drain epitaxy. For example, DCS has a relatively high growth rate. However, when using DCS to form the source/drain stressors, the in-situ doped p-type and n-type impurities have low concentrations that fail to meet the demanding high concentration of the CMOS devices formed using advanced technologies. Other precursors such as trisilane, on the other hand, may result in the epitaxy growth that has a poor orientation-selectivity in silicon trenches, and may result in the epitaxy regions that have undesirable shapes.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 through 9 are cross-sectional views of intermediate stages in the manufacturing of a metal-oxide-semiconductor (MOS) fin field-effect transistor (FinFET) in accordance with embodiments;

FIGS. 10 and 11 are cross-sectional views of intermediate stages in the manufacturing of a planar MOSFET in accordance with alternative embodiments; and

FIG. 12 illustrates a schematic diagram of an apparatus for performing epitaxy using hexachlorodisilane (HCDS) as a precursor.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

A method of forming silicon-containing source and drain regions is provided in accordance with embodiments. The intermediate stages of manufacturing various embodiments are illustrated. The variations of the embodiments are discussed. Throughout the various views and illustrative embodiments, like reference numbers are used to designate like elements.

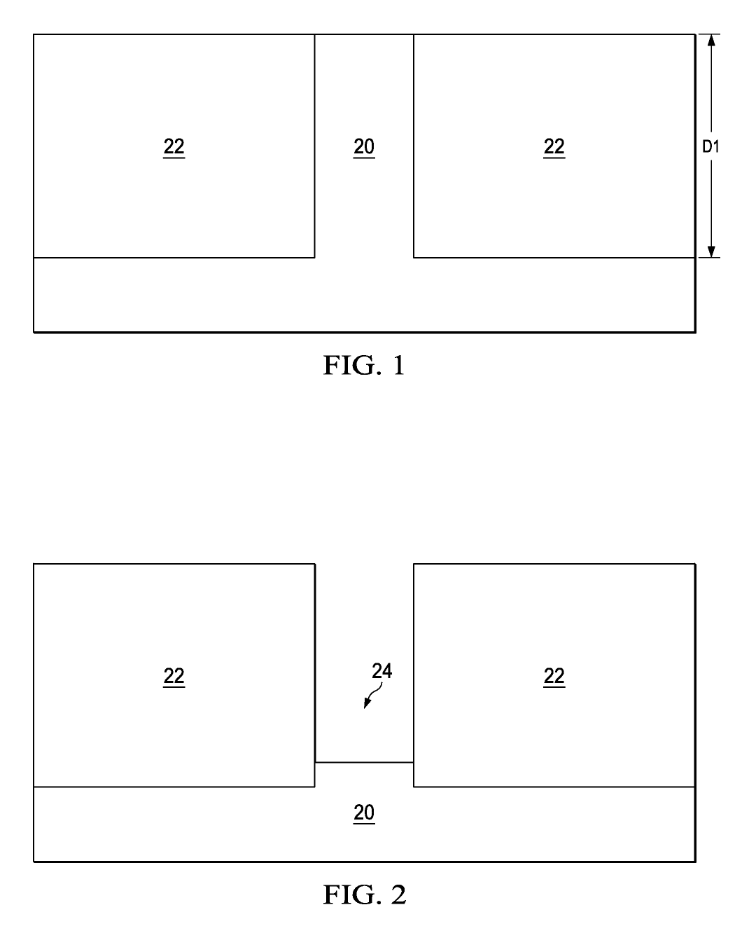

Referring to FIG. 1, substrate 20, which may be a portion of a semiconductor wafer, is provided. Substrate 20 may be a semiconductor substrate. In an embodiment, substrate 20 is a silicon substrate with no germanium therein, although it may also be formed of silicon germanium (SiGe). Insulators such as shallow trench isolation (STI) regions 22 are formed in substrate 20. Depth D1 of STI regions 22 may be between about 50 nm and about 300 nm, or between about 100 nm and about 400 nm. It is realized, however, that the dimensions recited throughout the description are merely examples, and may be changed to different values. STI regions 22 may be formed by recessing semiconductor substrate 20 to form openings, and then filling the openings with dielectric materials. STI regions 22 may include two neighboring regions having their sidewalls facing each other, with a portion of substrate 20 between, and adjoining, the two neighboring STI regions 22.

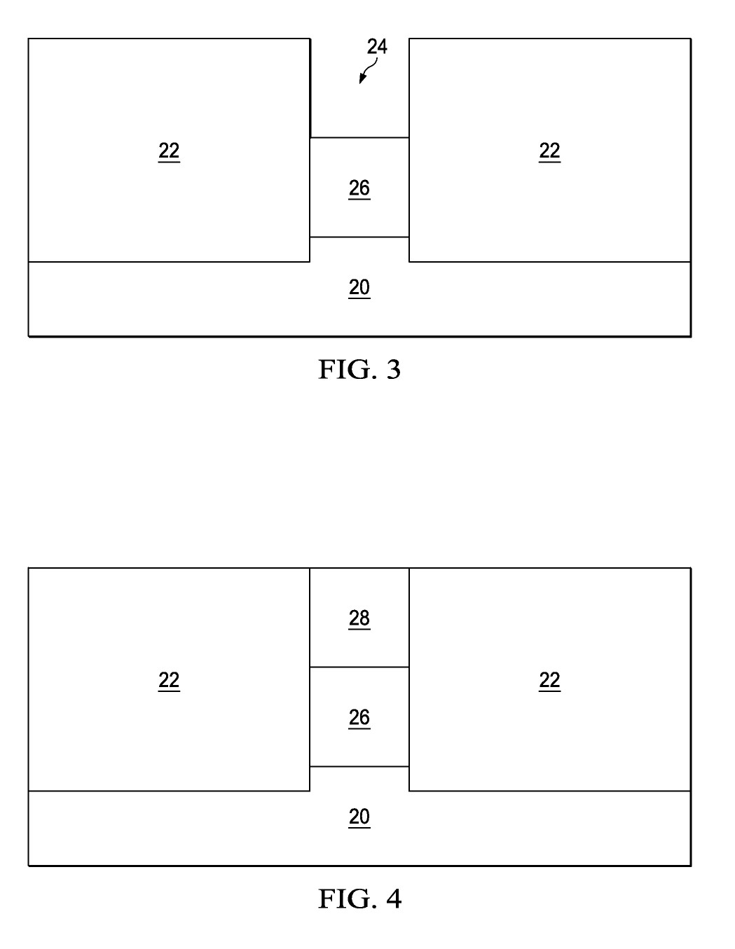

Referring to FIG. 2, the portion of substrate 20 that is between two neighboring STI regions 22 is removed, forming opening 24. In an embodiment, the bottom of opening 24 is level with the bottoms of STI regions 22. In alternative embodiments, the bottom of opening 24 may be lower than or higher than the bottoms of STI regions 22.

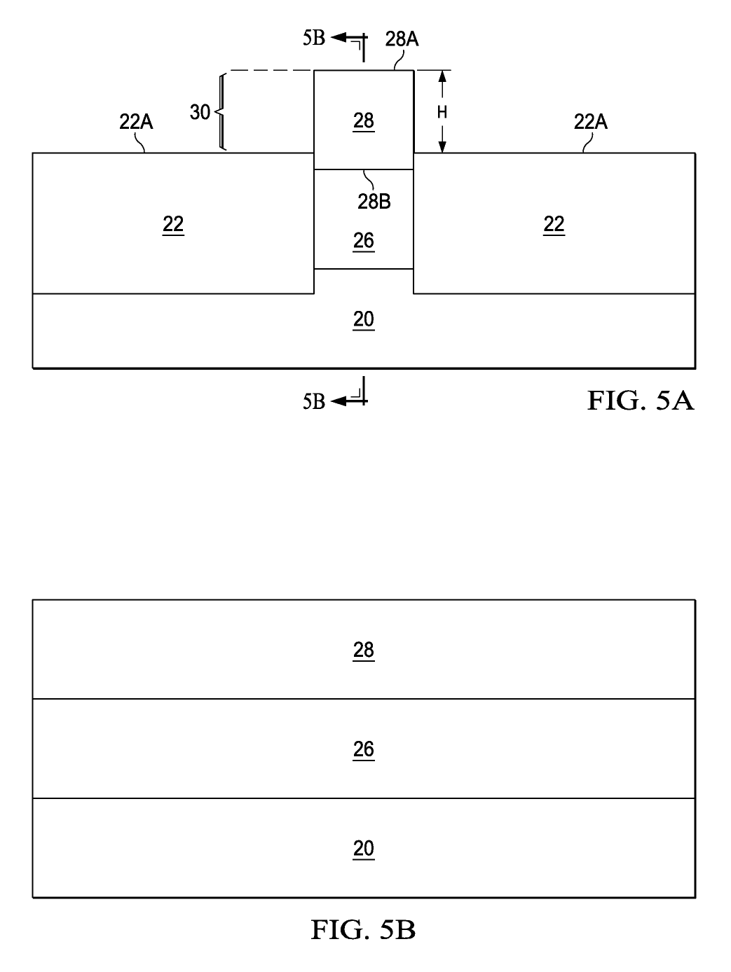

FIG. 3 illustrates the formation of SiGe layer 26 in opening 24. The methods for forming SiGe layer 26 include, for example, selective epitaxial growth (SEG). SiGe layer 26 may be expressed as Si₁₋ₓGeₓ, wherein x is the atomic percentage of germanium in the silicon germanium, and x is greater than 0, and may be equal to or less than 1. When x is equal to about 1, SiGe layer 26 is formed of substantially pure germanium. In an exemplary embodiment, x is between about 0.4 and about 0.5.

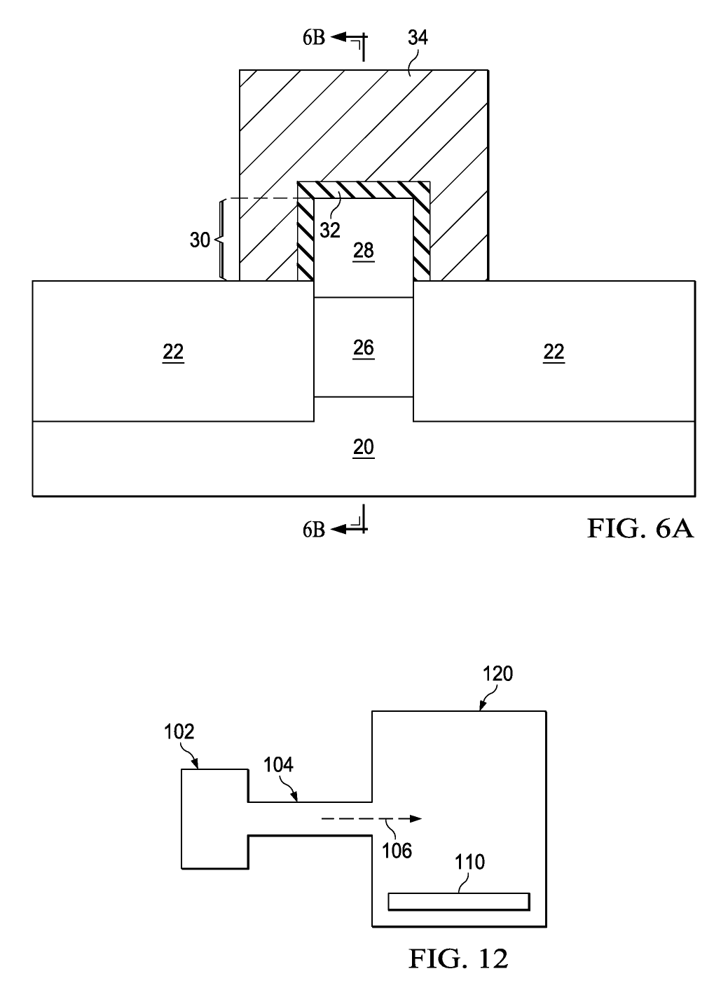

In FIG. 4, semiconductor layer 28 is epitaxially grown on SiGe layer 26. In an embodiment, semiconductor layer 28 is formed of silicon germanium, which may be expressed as Si_{1-y}Ge_{y}, wherein value y is the atomic percentage of germanium, and value y may be equal to or greater than 0, and equal to or less than 1. Atomic percentage y of semiconductor layer 28 may be smaller than (or greater than) atomic percentage x of silicon germanium layer 26. In an exemplary embodiment, atomic y is between about 0.3 and about 0.4. In other embodiments, semiconductor layer 28 is formed of substantially pure silicon. In yet other embodiments, semiconductor layer 28 may include a III-V compound semiconductor that comprises a group-III element and a group-V element. The III-V compound semiconductor may include, but is not limited to, GaAs, InP, GaN, InGaAs, InAlAs, GaSb, AlSb, AlAs, AlP, GaP, combinations thereof, and multi-layers thereof. Semiconductor layer 28 may have a lattice constant smaller than (or greater than) the lattice constant of silicon germanium layer 26. Accordingly, a compressive or tensile stress may be generated in semiconductor layer 28.

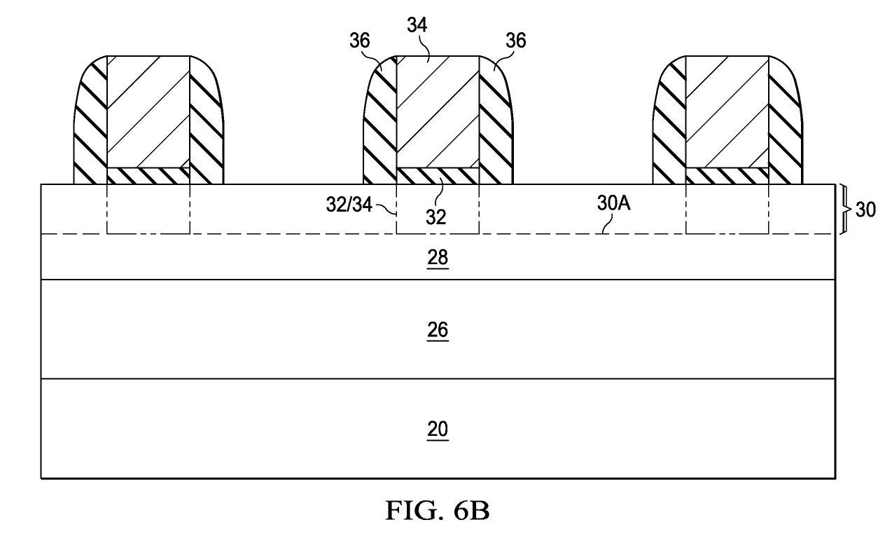

Referring to FIG. 5A, STI regions 22 are recessed, so that top surface 28A of semiconductor layer 28 is higher than top surfaces 22A of the remaining portions of STI regions 22. In an embodiment, top surfaces 22A may be at an intermediate level that is between top surface 28A and bottom surface 28B of semiconductor layer 28. In alternative embodiments, top surfaces 22A may be level with, or lower than, bottom surface 28B. Throughout the description, the portion of semiconductor layer 28 (and possibly SiGe layer 26) that are over top surfaces 22A is referred to as fin 30. Fin 30 has fin height H. In an exemplary embodiment, fin height H is between about 10 nm and about 50 nm. FIG. 5B illustrates a cross-sectional view of the structure shown in FIG. 5A, wherein the cross-sectional view is obtained from the vertical plane crossing line 5B-5B in FIG. 5A.

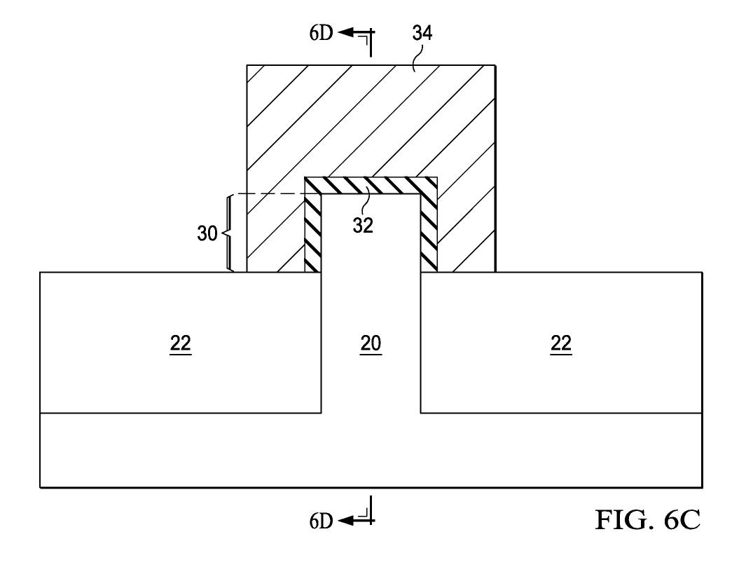

FIGS. 6A and 6B illustrate the formation of gate dielectric 32, gate electrode 34, and gate spacers 36. Referring to FIG. 6A, gate dielectric 32 is formed on the sidewalls and the top surface of fin 30. The material of gate dielectric 32 may include silicon oxide, silicon nitride, high-k dielectric materials such as Hf-containing dielectrics, and the like. Gate electrode 34 may be formed of polysilicon, metals, metal silicides, and the like. FIG. 6B is a cross-sectional view of the structure shown in FIG. 6A, wherein the cross-sectional view is obtained from the vertical plane crossing line 6B-6B in FIG. 6A. Gate spacers 36 are formed on the sidewalls of gate electrode 34. In FIG. 6B, dashed lines are used to illustrate the portions of gate dielectric 32 and gate electrode 34 that are on the sidewalls of fin 30, since these portions of gate dielectric 32 and gate electrode 34 are not in the plane of FIG. 6B. Furthermore, in FIG. 6B, the bottom level of fin 30 is marked as 30A.

In some embodiments as shown in FIGS. 2 through 5B, fin 30 is formed from epitaxy layer(s) that have different lattice constants from that of substrate 20. In alternative embodiments, the steps as shown in FIGS. 2 through 5B may be skipped, and fin 30 is formed of the same material as substrate 20. The cross-sectional views of the resulting structure is shown in FIGS. 6C and 6D, wherein the cross-sectional view as in FIG. 6D is obtained from the plane crossing line 6D-6D in FIG. 6C. The recess to STI regions 22 (FIG. 1) may be performed on the structure shown in FIG. 1, so that fin 30 (FIGS. 6C and 6D) comprises the same semiconductor material as that of substrate 20, which material may be silicon that is substantially free germanium.

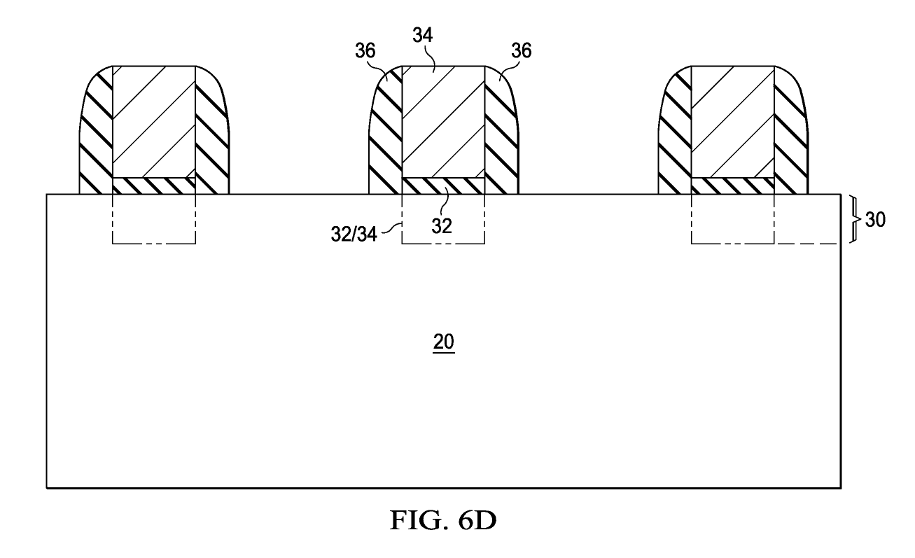

Referring to FIG. 7, which is a cross-sectional view obtained from the same plane as in FIG. 6B, recesses 40 are formed, for example, by etching into semiconductor layer 28. In an embodiment, recesses 40 extend into semiconductor layer 28, and do not extend into SiGe layer 26. In alternative embodiments, recesses extend down into SiGe layer 26. Depth D2 of recesses 40 may be between about one time to two times fin height H of fin 30. The edges of recesses 40 may be substantially vertically aligned to the outer edges of gate spacers 36. In other embodiments, recesses 40 may extend to directly underlying gate spacers 36. Dashed lines 42 illustrate the positions of the sidewalls and bottoms of recesses 40 in accordance with alternative embodiments.

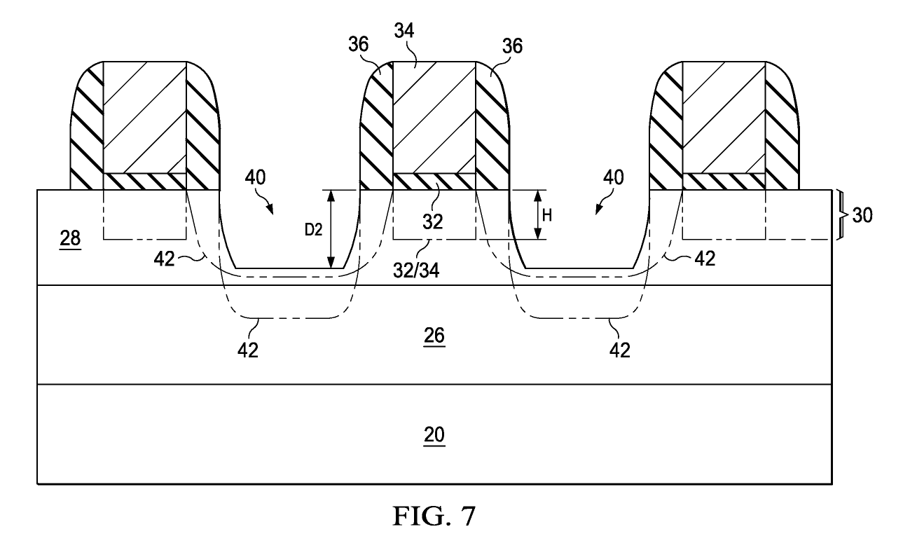

FIG. 8 illustrate the epitaxial growth of source/drain stressors 44, which may also be performed through the SEG. During the epitaxial growth of silicon-containing source/drain stressors 44 (which are also source/drain regions), hexachlorodisilane (HCDS, Si₂H₆) is used as a precursor for supplying silicon atoms. In an embodiment in which source/drain stressors 44 comprises silicon germanium (for example, when the respective FinFET is a p-type FinFET), an additional germanium-containing precursor such as germane (GeH₄) may be added. In alternative embodiments in which source/drain stressors 44 comprises silicon carbon (for example, when the respective FinFET is an n-type FinFET), an additional carbon-containing precursor may be added. Silicon-containing source/drain stressors 44 may also be silicon regions that are substantially free from germanium and carbon. In an embodiment, the epitaxy of source/drain stressors 44 is performed using a chemical vapor deposition (CVD) method such as low-pressure CVD (LPCVD), ultra low-pressure CVD (UHVCVD), or the like. The epitaxial growth of source/drain stressors 44 may be performed at temperatures between about 640° C. and about 680° C. The growth rate may be between about 0.8 nm/minute and about 1.7 nm/minute.

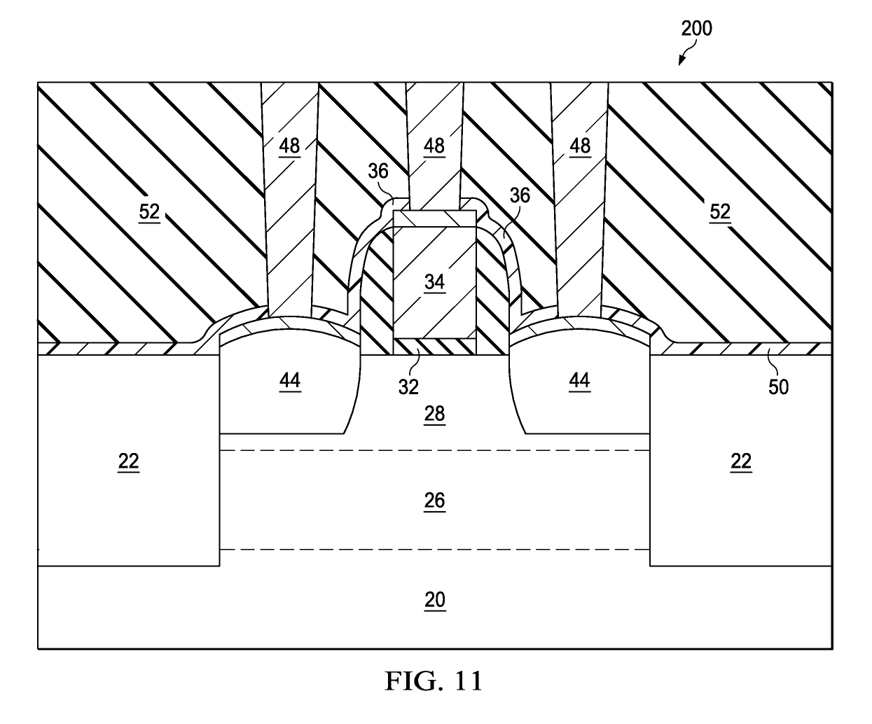

Since HCDS is in liquid form at the room temperature, for example, about 21° C., the apparatus for the epitaxy process as shown in FIG. 8 may need a bubble system. FIG. 12 illustrates a schematic block diagram of chamber 120, which may be configured to perform the methods such as LPCVD, UHVCVD, or other methods for the epitaxy of source/drain stressors 44 as in FIG. 8. Wafer 110, which includes the structure as in FIG. 7, is placed in chamber 120. Bubble system 102 is connected to chamber 120 through heating tube 104. Bubble system 102 is configured to generate HCDS vapor 106, which is conducted into chamber 120 through heating tube 104. Heating tube 104 may be maintained at the temperatures higher than about 150° C., and between about 170° C. and about 200° C., for example, to prevent HCDS vapor 106 from being condensed into a liquid in heating tube 104. Heating tube 104 may have a heat gradient, with the end closer to chamber 120 having a temperature higher than the end closer to bubble system 102.

Referring back to FIG. 8, in an embodiment in which the resulting MOS FET 100 is a p-type FinFET, a p-type impurity such as boron is in-situ doped with the proceeding of the epitaxy of source/drain stressors 44. In an exemplary embodiment, the precursor for doping boron comprises B₂H₆. Alternatively, in an embodiment in which the resulting MOS FET 100 is an n-type FinFET, an n-type impurity such as phosphorous is in-situ doped with the proceeding of source/drain stressors 44. In an exemplary embodiment, the precursor for doping phosphorous comprises PH₃. The resulting impurity concentration of the p-type or n-type impurity in source/drain stressors 44 may be between about 10¹⁹/cm³ and about 10²²/cm³, and may be higher than 10²²/cm³.

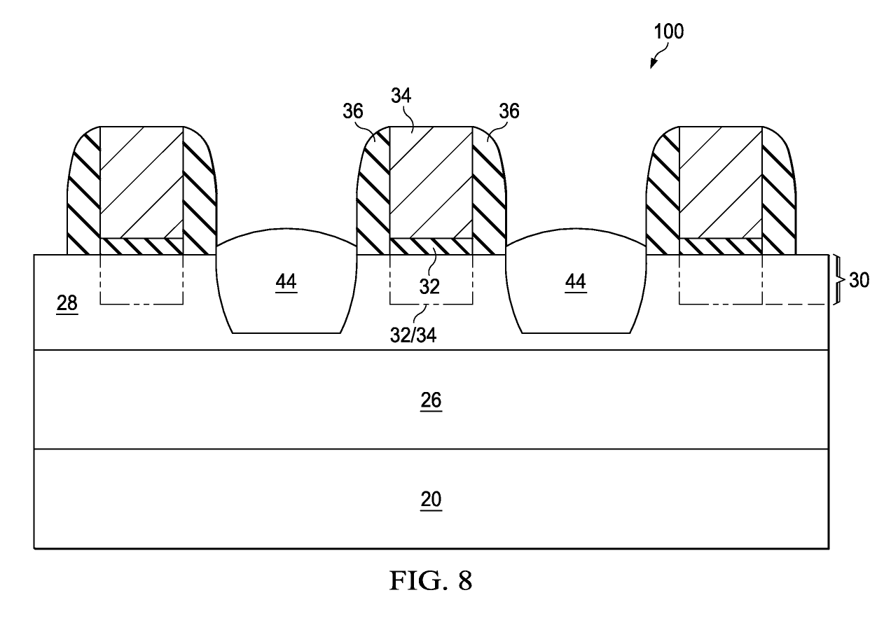

FIG. 9 illustrates the formation of the remaining components of FinFET 100, which components include silicide regions 46, contact plugs 48, contact etch stop layer 50, and inter-layer dielectric (ILD) 52. In the resulting FinFET 100, depending on the bottom position of recesses 40 (FIG. 7), source/drain stressors 44 may extend into SiGe layer 26, or alternatively, not extend into SiGe layer 26. Furthermore, source/drain stressors 44 may extend down to lower than bottom level 30A of fin 30, or have bottom surfaces substantially level with bottom level 30A of fin 30. Dashed lines 42 illustrate the positions of edges and bottoms of source/drain stressors 44 in accordance with alternative embodiments.

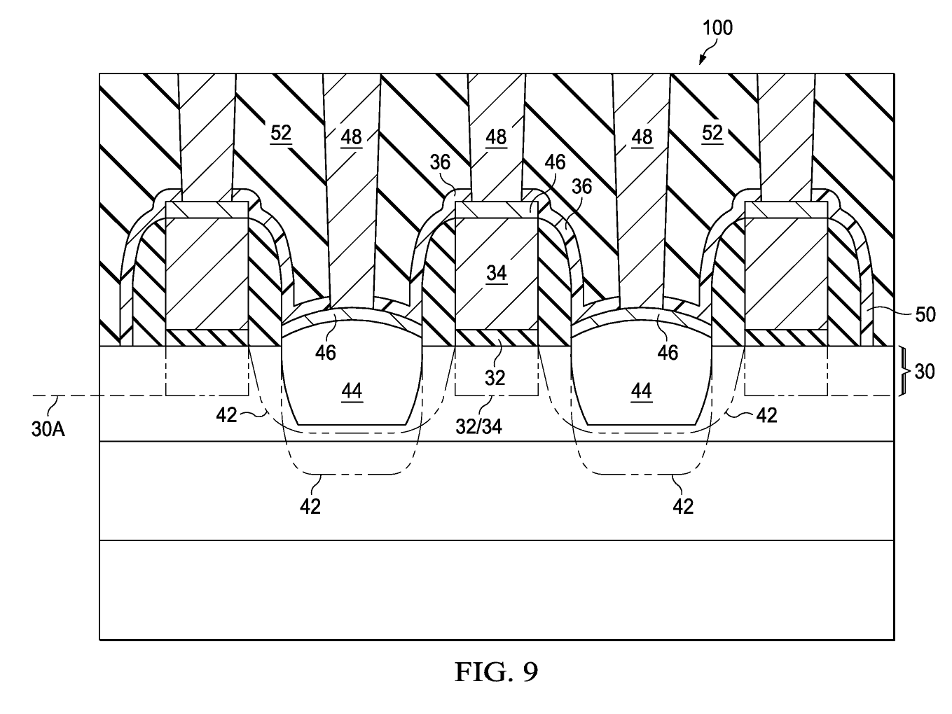

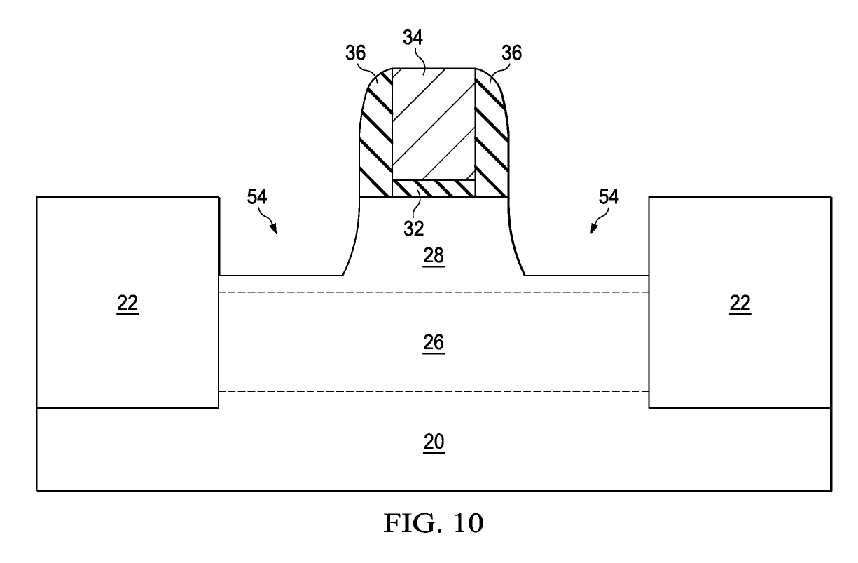

FIGS. 10 and 11 are cross-sectional views of intermediate stages in the manufacturing of planar FET 200 in accordance with alternative embodiments. Unless specified otherwise, the reference numerals in these embodiments represent like elements in the embodiments illustrated in FIGS. 1 through 9. The materials, dimensions, and the process steps for forming SiGe layer 26, semiconductor layer 28, and source/drain stressors 44 may be essentially the same as the formation of the respective components in FinFET 100. Referring to FIG. 10, STI regions 22 are formed in substrate 20. If planar FET 200 is a PFET, layers 26 and 28 may be formed using essentially the same process steps as shown in FIGS. 2 through 4 to incur a compressive stress in the channel region of planar FET 200. Otherwise, if planar FET 200 is an NFET, the steps as shown in FIGS. 2 through 4 may be skipped. The gate stack including gate dielectric 32 and gate electrode 34 is formed on substrate 20, followed by the formation of gate spacers 36. Recesses 54 are then formed in substrate 20 (or layer 28). Dashed lines 42 illustrate the alternative positions of the sidewalls and the bottoms of recesses 54.

Referring to FIG. 11, source/drain stressors 44 are formed by epitaxy, wherein HCDS is used as a precursor for supplying silicon in source/drain stressors 44. Similarly, in the formation of source/drain stressors 44, a p-type or an n-type impurity may be in-situ doped with the proceeding of the epitaxy. In subsequent process steps, silicide regions 46, contact plugs 48, contact etch stop layer 50, and ILD 52 are formed using essentially the same methods as for forming the corresponding components in FinFET 100.

In the embodiments, HCDS is used as the silicon-containing precursor in the epitaxy of the silicon-containing source/drain regions. The growth rate of the source/drain regions is high in the epitaxy process when HCDS is used. Since HCDS includes chlorine, the epitaxy has an etch-back effect, and hence the quality of the resulting silicon-containing source/drain regions is high, and the growth selectivity is high. In addition, a p-type impurity (such as boron) or an n-type impurity (such as phosphorous) may be in-situ to a high concentration, the resistivities of the source/drain regions are hence reduced.

In accordance with embodiments, a method includes forming a gate stack over a semiconductor region, and recessing the semiconductor region to form a recess adjacent the gate stack. A silicon-containing semiconductor region is epitaxially grown in the recess to form a source/drain region, wherein the step of epitaxially growing is performed using hexachlorodisilane as a precursor.

In accordance with other embodiments, a method includes forming isolation regions in a semiconductor substrate. The isolation regions are then recessed, wherein a semiconductor region between recessed portions of the isolation regions forms a semiconductor fin that is above top surfaces of remaining portions of the isolation regions. A gate stack is formed on a top surface and sidewalls of the semiconductor fin. The semiconductor fin is recessed to form recesses on opposite sides of the gate stack. Silicon-containing semiconductor regions are epitaxially grown in the recesses to form source/drain regions of a fin field-effect transistor (FinFET). The step of epitaxially growing is performed using hexachlorodisilane as a precursor.

In accordance with yet other embodiments, a method includes forming isolation regions in a silicon substrate, and forming a gate stack on a top surface of the silicon substrate. Portions of the silicon substrate on opposite sides of the gate stack are recessed to form recesses. Silicon-containing semiconductor regions are epitaxially grown in the recesses to form source/drain regions of a planar FET, wherein the step of epitaxially growing is performed using hexachlorodisilane as a precursor.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A method comprising:
forming a gate stack over a semiconductor region;
recessing the semiconductor region to form a recess adjacent the gate stack; and
epitaxially growing a silicon-containing semiconductor region in the recess to form a source/drain region, wherein the step of epitaxially growing is performed using hexachlorodisilane as a precursor.

2. The method of claim 1, wherein in the step of epitaxially growing the silicon-containing semiconductor region, a p-type or an n-type impurity is in-situ doped.

3. The method of claim 1, wherein the silicon-containing semiconductor region comprises silicon germanium.

4. The method of claim 1, wherein the silicon-containing semiconductor region is substantially free from germanium.

5. The method of claim 1, wherein the gate stack and the source/drain region form a fin field-effect transistor (FinFET), and wherein the method further comprises:
before the step of forming the gate stack, forming isolation regions in a semiconductor substrate; and
recessing the isolation regions, wherein the semiconductor region between recessed portions of the isolation regions forms a semiconductor fin that is above top surfaces of remaining portions of the isolation regions, and wherein the gate stack comprises a first portion directly over the semiconductor fin, and a second portion on a sidewall of the semiconductor fin.

6. The method of claim 1, wherein the gate stack and the source/drain region form a planar transistor.

7. The method of claim 1 further comprising:
generating a hexachlorodisilane vapor from a hexachlorodisilane liquid; and
conducting the hexachlorodisilane vapor into a chamber to perform the step of epitaxially growing the silicon-containing the semiconductor regions in the chamber.

8. A method comprising:
forming isolation regions in a semiconductor substrate;
recessing the isolation regions, wherein a semiconductor region between recessed portions of the isolation regions forms a semiconductor fin that is above top surfaces of remaining portions of the isolation regions;
forming a gate stack on a top surface and sidewalls of the semiconductor fin;
recessing the semiconductor fin to form recesses on opposite sides of the gate stack; and
epitaxially growing silicon-containing semiconductor regions in the recesses to form source/drain regions of a fin field-effect transistor (FinFET), wherein the step of epitaxially growing is performed using hexachlorodisilane as a precursor.

9. The method of claim 8, wherein the FinFET is a p-type field-effect transistor (PFET), and wherein the method further comprises:
etching a portion of the semiconductor substrate between opposite sidewalls of the isolation regions to form a recess; and
epitaxially growing a silicon germanium region in the recess to form the semiconductor region, wherein the semiconductor fin comprises at least a portion of the silicon germanium region.

10. The method of claim 8, wherein the step of epitaxially growing the silicon-containing semiconductor regions comprises growing silicon germanium regions.

11. The method of claim 8, wherein the step of epitaxially growing the silicon-containing semiconductor regions comprises growing silicon regions that are substantially free from germanium.

12. The method of claim 8, wherein in the step of epitaxially growing the silicon-containing semiconductor regions, a p-type or an n-type impurity is in-situ doped.

13. The method of claim 8 further comprising:
generating a hexachlorodisilane vapor from a hexachlorodisilane liquid; and
conducting the hexachlorodisilane vapor into a chamber to perform the step of epitaxially growing the silicon-containing semiconductor regions.

14. The method of claim 13, wherein the hexachlorodisilane vapor is conducted into the chamber through a gradient heating tube.

15. A method comprising:
forming isolation regions in a silicon substrate;
forming a gate stack on a top surface of the silicon substrate;
recessing portions of the silicon substrate on opposite sides of the gate stack to form recesses; and
epitaxially growing silicon-containing semiconductor regions in the recesses to form source/drain regions of a planar field-effect transistor (FET), wherein the step of epitaxially growing is performed using hexachlorodisilane as a precursor.

16. The method of claim 15, wherein the step of epitaxially growing the silicon-containing semiconductor regions comprises growing silicon germanium regions.

17. The method of claim 15, wherein the step of epitaxially growing the silicon-containing semiconductor regions comprises growing silicon regions that are substantially free from germanium.

18. The method of claim 15 further comprising:
generating a hexachlorodisilane vapor from a hexachlorodisilane liquid; and
conducting the hexachlorodisilane vapor into a chamber to perform the step of epitaxially growing silicon-containing semiconductor regions.

19. The method of claim 18, wherein the hexachlorodisilane vapor is conducted into the chamber through a gradient heating tube.

20. The method of claim 15, wherein in the step of epitaxially growing the silicon-containing semiconductor regions, a p-type or an n-type impurity is in-situ doped.
